(19) United States
(12) Patent Application Publication
(10) Pub. No.: US 2003/0070606 A1
(43) Pub. Date: Apr. 17, 2003

(54) Preparation of feedstock of alkaline earth and alkali metal fluorides

(76) Inventors: Nicolas LeBlond, Conring, NY (US); Alexandre M. Mayolet, Auneau (FR); Michael A. Pell, (US); Joseph M. Whalen, Corning, NY (US)

Correspondence Address: CORNING INCORPORATED, SP-TI-3-1, CORNING, NY, 14831

(21) Appl. No.: 10/263,048

(22) Filed: Oct. 1, 2002

Related U.S. Application Data
(60) Provisional application No. 60/327,654, filed on Oct. 5, 2001.

(51) Int. Cl. C30B 25/00; C30B 28/12; C30B 1/10

(52) U.S. Cl. 117/84; 117/200

(57) ABSTRACT

A method for making a below 200-nm wavelength optical fluoride crystal feedstock includes loading a fluoride raw material into a chamber, exposing the fluoride raw material to a flow of gaseous fluoride at a predetermined temperature, and storing the exposed fluoride raw material in a dry atmosphere.

### BACKGROUND OF THE INVENTION

1. Field of the Invention

The invention relates generally to methods for removing oxide impurities from metal salts. More specifically, the invention relates to a method for preparing feedstock of alkaline earth and alkali metal fluoride salts and use of the feedstock in manufacturing optical fluoride crystals.

2. Background Art

Crystals of alkaline earth and alkali metal fluoride salts are useful materials because of their low-wavelength absorption edges. Crystals of fluoride salts such as CaF₂, BaF₂, SrF₂, LiF, MgF₂, and NaF are useful in applications that require high transmission in the vacuum ultraviolet (VUV) region, i.e., at wavelengths below 200 nm.

Single fluoride crystals are commonly grown using the Bridgman-Stockbarger process. This process is described with reference to FIGS. 1A and 1B. In FIG. 1A, a fluoride raw material F is loaded into a crucible C, which is disposed inside a hot zone HZ of a vertical furnace 1. The hot zone HZ is then heated to a temperature sufficient to melt the fluoride raw material F. After melting the fluoride raw material F, the crucible C is slowly lowered from the hot zone HZ to a cold zone CZ, as shown in FIG. 1B. As the crucible C passes from the hot zone HZ to the cold zone CZ, the molten material F goes through a zone of thermal gradient. On passing through this zone, the temperature transition inside the molten material F creates a crystal front CF. The crystal front CF propagates inside the crucible C, within the material F, as long as the crucible C is caused to move downwardly.

It has been found that oxide impurities in fluoride crystals can have a degrading effect on VUV transmission of the crystals. The oxide impurities are attributed primarily to the reaction of water molecules with the fluorides and residual carbonates. Unfortunately, it is difficult to avoid oxide contamination in the crystals because water is ubiquitous. Water molecules are usually found in the raw material used in preparing the crystals as well as during the crystal growth process. A common strategy for reducing the oxide content in crystals is to react an oxide scavenger with the raw material prior to growing the crystal, i.e., prior to moving the melted raw material through a thermal gradient. This reaction may be carried out separately from the crystal growth process or as part of the crystal growth process.

### SUMMARY OF INVENTION

In one aspect, the invention relates to a method for making a below 200-nm wavelength optical fluoride crystal feedstock which comprises loading a fluoride raw material into a chamber, exposing the fluoride raw material to a flow of gaseous fluoride at a predetermined temperature, and storing the exposed fluoride raw material in a dry atmosphere.

In another aspect, the invention relates to a method for making a below 200-nm wavelength optical fluoride crystal feedstock which comprises loading a fluoride raw material in powder form into a chamber, exposing the fluoride raw material to a flow of gaseous fluoride at a predetermined temperature, agitating the chamber so as to expose surfaces of the fluoride raw material to the flow of gaseous fluoride, and storing the exposed fluoride raw material in a dry atmosphere.

In another aspect, the invention relates to a method for manufacturing an optical crystal for transmitting light of a wavelength less than 200 nm which comprises loading a fluoride raw material treated by exposure to a flow of gaseous fluoride into a crucible, adding a solid fluorinating agent to the fluoride raw material, melting the fluoride raw material and solid fluorinating agent, and growing the crystal by moving the melted fluoride raw material through a thermal gradient.

In another aspect, the invention relates to a method for manufacturing an optical fluoride crystal for transmitting light of a wavelength less than 200 nm which comprises loading a fluoride raw material into a controlled atmosphere chamber, heating the fluoride raw material to a predetermined temperature, exposing the fluoride raw material to a drying inert gas at least through a portion of the heating the fluoride raw material to the predetermined temperature, exposing the fluoride raw material to a flow of gaseous fluoride at the predetermined temperature to provide a fluoride raw material having a maximum oxygen content of 100 ppm, melting the fluoride raw material having a maximum oxygen content of 100 ppm, and crystallizing the melted fluoride raw material to form a crystal having an internal transmission of at least 95%/cm at 157 nm.

In another aspect, the invention relates to an optical fluoride crystal blank for transmitting light of a wavelength less than 200 nm. The optical fluoride crystal has a maximum oxygen content of 100 ppm, more preferably having an oxygen content <50 ppm by weight, more preferably having an oxygen content <20 ppm by weight, and most preferably having a maximum oxygen content of 12 ppm by weight, and an internal transmission of at least 95%/cm at 157 nm.

In another aspect, the invention relates to an apparatus for removing oxide impurities from a fluoride salt which comprises a chamber into which the fluoride salt is loaded. The chamber has an inlet end and an outlet end. The apparatus further comprises a pair of porous membranes, each of which covers one of the inlet and outlet ends of the chamber, means for rotating the chamber, and means for heating the chamber.

Other features and advantages of the invention will be apparent from the following description and the appended claims.

### BRIEF DESCRIPTION OF DRAWINGS

FIGS. 1A and 1B illustrate a process for forming a crystal.

FIG. 2 shows an apparatus for purifying a fluoride raw material according to an embodiment of the invention.

FIG. 3 is a flowchart illustrating a method for preparing a feedstock of a fluoride raw material according to an embodiment of the invention.

FIG. 4 is a graph of oxygen level versus exposure time for different fluoride treatment temperatures.

FIG. 5 shows the reaction chamber and vessel of FIG. 2 supported for rotation according to one embodiment of the invention.

### DETAILED DESCRIPTION

Embodiments of the invention provide a method for preparing a feedstock of alkaline earth and alkali metal fluorides. The feedstock prepared by the method of the invention can be used for growing optical crystals, such as single crystals of CaF₂, BaF₂, SrF₂, LiF, MgF₂, and NaF and mixtures of these crystals, with preferred mixtures being mixtures of CaF₂+BaF₂+SrF₂, CaF₂+BaF₂, or CaF₂+SrF₂ The feedstock prepared by the method of the invention can also be used for growing mixed crystals, such as M₃AlF₆, where M is Li, Na, K, Rb, or Cs. The feedstock prepared by the method of the invention can also be used for fabricating multi-component fluoride glasses such as fluorozirconate glass and BeF₂-containing glasses.

The method generally involves heating a fluoride raw material and exposing the heated fluoride raw material to a gaseous fluoride to remove oxide impurities in the fluoride raw material. The purification process can be performed below, at, or above melting point. The purification process is carried out in a reactor, which is separate from the furnace used in growing the crystal. One advantage of this separation is that the furnace elements, e.g., crucibles, resistors, and thermocouples, are protected from attack by the gaseous fluoride. Another advantage is that large amounts of raw material can be treated at once, freeing up time in the crystal growth furnace, which is usually a higher capital investment. The invention provides a mechanism for increasing the surface area of the raw material exposed to the gaseous fluoride when treating large amounts of powder.

In the following detailed description of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

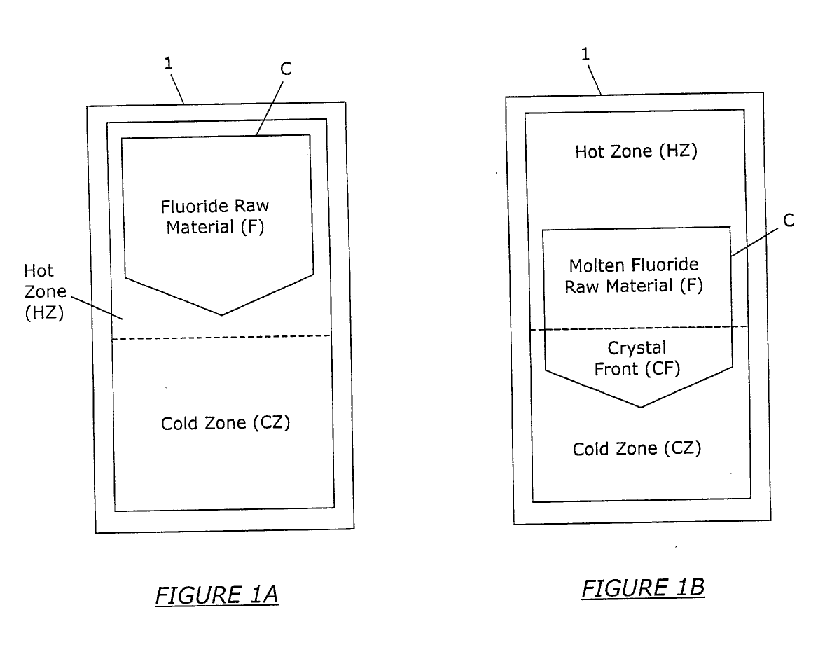

FIG. 1 is a schematic of an exemplary apparatus 2 for practicing the invention. The apparatus 2 includes a reaction chamber 4 constructed from an inert material, such as graphite, boron nitride, silicon nitride, silicon carbide, quartz, or alumina. In one embodiment, the reaction chamber 4 is generally cylindrical in shape with the axial axis of the cylinder generally aligned along a horizontal axis x. Alternatively, the axial axis of the cylinder may be generally aligned along a vertical axis y. In alternate embodiments, the reaction chamber 4 may have other shape, e.g., spherical. The inlet end 6 and the outlet end 8 of the reaction chamber 4 are covered with porous membranes 10, 12, respectively. In one embodiment, the porous membranes 10, 12 are made of an inert material, such as graphite, boron nitride, silicon nitride, silicon carbide, quartz, or alumina.

In one embodiment, the reaction chamber 4 is encased within a reaction vessel 14, which may be made of a corrosion-resistant material such as stainless steel. In the illustration, the reaction vessel 14 has one or more inlet ports 16 (only one is shown) and one or more outlet ports 18 (only one is shown). The inlet port 16 is coupled to a gas source 20, and the outlet port 18 is connected to a treatment chamber 22.

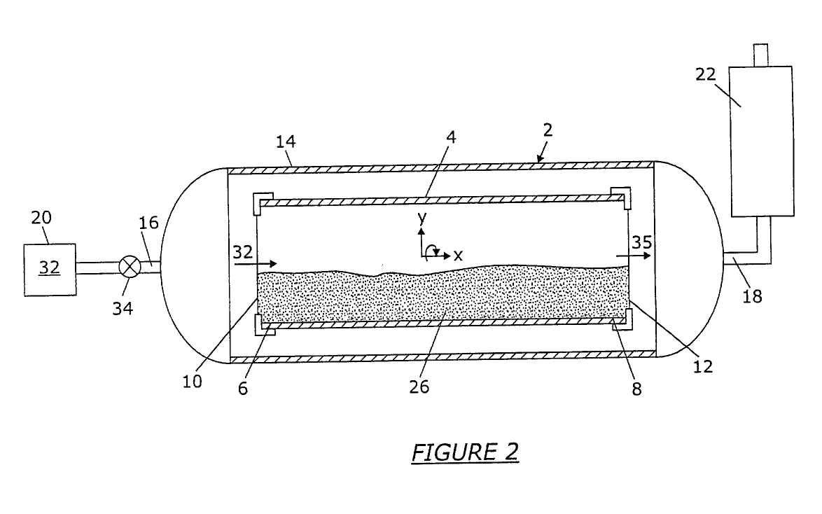

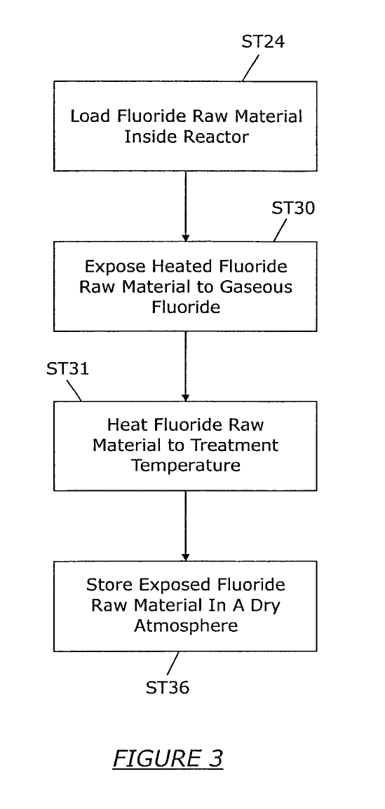

FIG. 3 is a flowchart illustrating a process for preparing a feedstock of a fluoride salt according to one embodiment of the invention. At ST24, the process starts by loading a relatively pure fluoride raw material (26 in FIG. 2) in powder (or granular) form into the reaction chamber (4 in FIG. 2). The fluoride raw material (26 in FIG. 2) can have a high oxygen content, e.g., much greater than 200 ppm by weight. The fluoride raw material (26 in FIG. 2) is contained within the reaction chamber (4 in FIG. 2) by the porous membranes (10, 12 in FIG. 2). The reaction chamber (4 in FIG. 2) is then loaded into the reaction vessel (14 in FIG. 2). After loading the reaction chamber (4 in FIG. 2) inside the reaction vessel (14 in FIG. 2), the reaction vessel (14 in FIG. 2) may be purged with a pure inert gas, such as argon, helium, or nitrogen, or degassed to vacuum pressure (e.g., 10⁻⁵ torr or less).

At ST30, the fluoride raw material (26 in FIG. 2) is heated to a temperature, which may be below, at, or above a melting point of the raw material. Typically, the fluoride raw material is heated to a temperature in a range from 50° C. below to 100° C. above the melting point of the raw material. The fluoride raw material (26 in FIG. 2) may be heated, for example, by direct resistive heating of the reaction vessel (14 in FIG. 2). In alternate embodiments, the reaction vessel (14 in FIG. 2) may be placed in a furnace, or the reaction chamber (4 in FIG. 2) may be placed directly in the furnace. In either case, heaters in the furnace would provide the heat to the fluoride raw material (26 in FIG. 2). Alternatively, a heated gas may be passed over the fluoride raw material (26 in FIG. 2) to provide the necessary heat to the fluoride raw material (26 in FIG. 2).

The inert gas used in purging the reaction vessel (14 in FIG. 2) may provide a dehydrating effect on the fluoride raw material (26 in FIG. 2). At ST30, a drying inert gas may also be passed over the fluoride raw material (26 in FIG. 2) to provide a dried heated fluoride raw material (26 in FIG. 2). The fluoride raw material (26 in FIG. 2) may be exposed to the drying inert gas through a portion of the heating step, e.g., at temperatures ranging from 400 to 800° C., or through the entire heating step.

The fluoride raw material (26 in FIG. 2) is heated to a desired treatment temperature and maintained at this temperature. At ST31, the fluoride raw material (26 in FIG. 2) is exposed to the reactive gas (32 in FIG. 2). The reactive gas (32 in FIG. 2) is introduced into the reaction chamber (4 in FIG. 2) through the inlet port (16 in FIG. 2) and porous membrane (10 in FIG. 2). In one embodiment, the reactive gas (32 in FIG. 2) is a gaseous fluoride. The gaseous fluoride reacts with the oxide impurities in the fluoride raw material (26 in FIG. 2) to produce volatile gases, which are carried away to the treatment chamber (22 in FIG. 2).

Examples of suitable gaseous fluorides include, but are not limited to, CF₄, NF₃, SF₆, BF₃, C₂F₄, HF, and F₂. In an embodiment the gaseous fluorides are gaseous carbon fluorides, such as CF₄, C₂F₄, CF₃Cl, CF₂Cl₂, CFCl₃ and mixtures thereof. In an embodiment the gaseous carbon fluorides are gaseous carbon fluoride chlorides, such as CF₃Cl, CF₂Cl₂, CFCl₃ and mixtures thereof. Mixtures of these gaseous fluorides may also be used. The gaseous fluoride used would typically be selected on the decomposition temperature of the gaseous fluoride and the melting point of the fluoride raw material. For example, CF₄ has high bond energy (536 KJ/mol) and is expected to be an effective oxide scavenger at temperatures above 1000° C. NF₃ and SF₆ should be able to produce similar scavenging effect at temperatures closer to 200 to 400° C. and 500 to 800° C., respectively, which is better suited for the treatment of low-melting raw materials.

The following equations show chemical reactions between the gaseous fluorides CF₄, NF₃, SF₆, and C₂F₄, respectively, and oxide impurities. In the equations below, M stands for alkaline earth metal. Charge-balanced equations similar to the ones shown below may be written for oxides of alkali metal, aluminum, zirconium, or other desired metal

CF₄+2MO (contaminant)→2MF₂+C0₂(g) (1)

2NF₃+3MO (contaminant)→3MF₂+NO₂(g)+NO(g) (2)

SF₆+3MO (contaminant)→3MF₂+SO₃(g) (3)

C₂F₄+2MO (contaminant)→2MF₂+2CO (g) (4)

XeF₂ is another example of a fluorinating agent that may be used to treat the fluoride raw material (26 in FIG. 2). XeF₂ exists as a white solid at room temperature and atmospheric pressure. Therefore, it is necessary to convert XeF₂ into the gaseous phase in a separate step before exposing the fluoride raw material (26 in FIG. 2) to XeF₂. XeF₂ has a triple point at 129° C. and a low vapor pressure of 0.5 KPa at 25° C. The temperature and pressure of XeF₂ can be suitably adjusted to convert XeF₂ into the gas phase. At room temperature, for example, XeF₂ sublimates at a pressure of about 4 torrs. XeF₂ may be converted to the gas phase by placing it in a vacuum system.

The reactive gas or gaseous fluoride (32 in FIG. 2) is typically supplied into the reaction chamber (4 in FIG. 2) at a flow rate that is dependent on the temperature of the fluoride raw material (26 in FIG. 2). A control valve (34 in FIG. 2) is used to control the flow rate of the gaseous fluoride (32 in FIG. 2). Further, the gaseous fluoride (32 in FIG. 2) is typically carried into the reaction chamber (4 in FIG. 2) in a stream of inert gas, such as argon, helium, or nitrogen. The amount of gaseous fluoride (32 in FIG. 2) in the inert gas stream may be in a range from 1% to 100% by weight. The inert gas may be premixed with the gaseous fluoride (32 in FIG. 2) or provided from a separate source (not shown). In the latter case, a separate control valve would be provided to control the rate at which the inert gas is supplied to the inlet port (16 in FIG. 2). In addition to exposing the fluoride raw material to a flow of gaseous fluoride at a predetermined temperature the invention includes exposing the fluoride raw material to a flow of gaseous fluoride at a predetermined pressure. In one embodiment, the flow rate of the inert gas is adjusted such that the predetermined pressure in the reaction vessel (14 in FIG. 2) is less than 5 atm and, preferably, around 1(±0.2) atm. In a preferred embodiment the pressure is no greater than 1 atm, more preferred less than 0.8 atm., more preferred less than 0.2 atm., and most preferred about 0.1 (±0.05) atm.

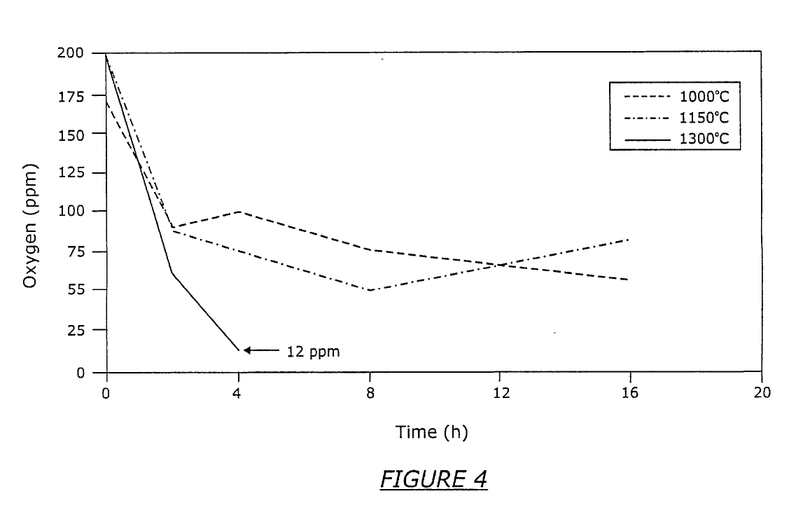

The fluoride raw material (26 in FIG. 2) is exposed to the gaseous fluoride (32 in FIG. 2) for a predetermined length of time. The amount of oxide impurities removed from the fluoride raw material (26 in FIG. 2) can be related to the exposure time and treatment temperature. FIG. 4 shows a plot of oxygen content versus time for CaF₂ treated with 25% CF₄ in He. Note that the time required to remove oxide impurities decreases as treatment temperature increases. At 1300° C., it takes about 4 hours to reduce oxygen content in the raw material from about 200 ppm to below 12 ppm. At 1000° C. and 1150° C., the oxygen content is higher than 50 ppm after 16 hours of treatment. The results show that the closer the treatment temperature is to the melting point of the raw material, the shorter the time required to reduce oxide impurities in the raw material.

As previously mentioned, the gaseous fluoride (32 in FIG. 2) reacts with oxide impurities in the fluoride raw material (26 in FIG. 2) to produce volatile gases (35 in FIG. 2), which are carried away by the gas stream to the treatment chamber (22 in FIG. 2). The treatment chamber (22 in FIG. 2) may include a scrubber (not shown) to remove or decompose any unreacted gaseous fluoride. Examples of scrubbers include heated metal oxide such as soda lime or a plasma system for decomposing CF₄. After exposing the fluoride raw material (14 in FIG. 2) to the gaseous fluoride (32 in FIG. 2) for a selected period of time, the treated raw material is removed from the reaction chamber (4 in FIG. 2) and stored under a dry atmosphere (ST36), e.g., an atmosphere having H₂O content of 1 ppm or less. This dry atmosphere may be provided by a sealed container that is purged with an inert gas, such as nitrogen and/or helium, or by a container that is sealed under vacuum.

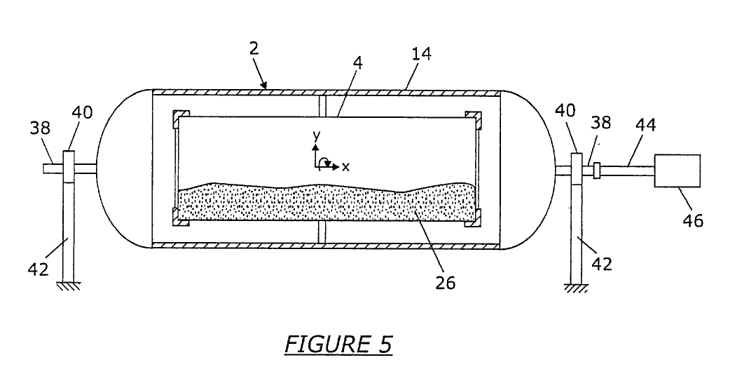

When treating large amounts of powder (e.g., greater than 10 kg), particularly at temperatures below the melting point of the powder, it may be difficult to expose all surfaces of the powder to the gaseous fluoride. Therefore, the invention provides a mechanism that allows all surfaces of the powder to be exposed to the gaseous fluoride. The mechanism basically includes agitating the reaction chamber (4 in FIG. 2) during fluoride treatment such that all surfaces of the powder are exposed to the gaseous fluoride (32 in FIG. 2). One method for agitating the reaction chamber (4 in FIG. 2) includes rotating the reaction chamber continuously or intermittently. Alternatively, shaking the reaction chamber (4 in FIG. 2) or other suitable agitation of the reaction chamber (4 in FIG. 2) can be used to expose surfaces of the powder to the gaseous fluoride (32 in FIG. 2).The reaction chamber (4 in FIG. 2) may be supported so as to be rotatable about the x-axis. In alternate embodiments, the reaction chamber (4 in FIG. 2) may be supported so as to be rotatable about the y-axis or at an angle to the x- or y-axis. In an alternate embodiment, the reaction chamber (4 in FIG. 2) may be fixed to the reaction vessel (14 in FIG. 2) and rotated simultaneously with the reaction vessel (14 in FIG. 2. As shown in FIG. 5, the reaction vessel 14 has shaft ends 38 supported by bearings 40. The bearings 40 are attached to support frames 42. One of the shafts 38 is coupled to a drive shaft 44 that is connected to a drive system 46, e.g., drive motor and gear train. The drive system 46 can be operated to rotate both the reaction vessel 14 and the reaction chamber 4. Rotary/flexible couplings (not shown) can be used to couple the inlet port 16 and outlet port 18 to the gas source 30 and treatment chamber 22, respectively. During the fluorine treatment, the reaction chamber 4 is agitated, e.g., by rotating continuously or intermittently, typically at a speed in a range from 0 to 200 rpm. Typically, the rotational speed will depend on factors such as the weight of the powder and the particle size. In one embodiment, the reaction chamber 4 is rotated such that the fluoride raw material 26 spins until the force of gravity overcomes the centrifugal force and the fluoride raw material 26 falls to the bottom of the spinning reaction chamber 4. This is similar to the mechanism of clothes spinning in the dryer. In this manner, fresh powder can be exposed to the gaseous fluoride 32.

Feedstock produced by the method described above has been used to grow crystals with internal transmission exceeding 95% and as high as 99.5% at 157 nm. Typically, the oxygen content of the feedstock is less than or equal to 100 ppm. Feedstock produced by the method described above can also be used to produce oriented crystals, e.g., crystals oriented along 111 or 001. (Seed crystals are needed to produce the oriented crystals.) Typically, small amounts of a solid fluorinating agent, e.g., PbF₂ or ZnF₂ or XeF₂, or mixtures thereof are added to the feedstock during the crystal growth process. The amount of solid fluorinating agent added to the feedstock is typically less than 2% by weight to minimize the presence of metal impurities in the crystal, preferably the amount of the solid fluorinating agent added to the fluoride raw material is at most 1% by weight, more preferably at most 0.5% by weight, more preferably at most 0.1% by weight. The purpose of the solid fluorinating agent is to scavenge oxide impurities that may have come in contact with the feedstock while loading the feedstock from the dry atmosphere into the crucible and/or furnace used in growing the crystal. In a preferred embodiment the invention includes providing a fluoride raw material having an oxygen content >100 ppm by weight, loading the fluoride raw material into a controlled atmosphere chamber; heating the fluoride raw material to a predetermined temperature; exposing the fluoride raw material to a drying inert gas at least through a portion of the heating the fluoride raw material to the predetermined temperature; exposing the fluoride raw material to a flow of gaseous fluoride at the predetermined temperature to provide a fluoride raw material having a maximum oxygen content of 50 ppm by weight; loading the fluoride raw material exposed to the flow of gaseous fluoride into a crucible, adding a solid fluorinating agent to the fluoride raw material prior to melting the fluoride raw material and melting the fluoride raw material having a maximum oxygen content of 50 ppm by weight; and crystallizing the melted fluoride raw material to form a fluoride crystal having a maximum oxygen content of 50 ppm by weight and an internal transmission of at least 95%/cm at 157 nm. Preferably the flow of gaseous fluoride includes a carbon fluoride (preferably CF₄) and the fluoride raw material having an oxygen content >100 ppm by weight is comprised of CaF₂ and said predetermined temperature is at least 1000 degrees C. In a preferred embodiment the invention includes providing a fluoride raw material comprised of barium fluoride, the fluoride raw material having an oxygen content >100 ppm by weight, loading the fluoride raw material into a controlled atmosphere chamber; heating the fluoride raw material to a predetermined temperature; exposing the fluoride raw material to a drying inert gas at least through a portion of the heating the fluoride raw material to the predetermined temperature; exposing the fluoride raw material to a flow of gaseous fluoride at the predetermined temperature to provide a fluoride raw material having a maximum oxygen content of 50 ppm by weight, the flow of gaseous fluoride including F₂; loading the fluoride raw material exposed to the flow of gaseous fluoride into a crucible, adding a solid fluorinating agent to the fluoride raw material prior to melting the fluoride raw material and melting the fluoride raw material having a maximum oxygen content of 50 ppm by weight; and crystallizing the melted fluoride raw material to form a fluoride crystal comprised of barium fluoride having a maximum oxygen content of 50 ppm by weight and an internal transmission of at least 95%/cm at 157 nm. Preferably the invention includes storing the exposed fluoride raw material in a sealed dry atmosphere between said exposing and said loading into a crucible and melting, most preferably with storing the exposed fluoride raw material for a maximum duration of 60 days. In a preferred embodiment the exposed fluoride raw material is in a particulate powder form, stored in such a powder form, and loaded into the crucible in such a powder form.

One of the effects of the fluorine treatment described above is densification. The fluoride raw material (26 in FIG. 2) has a higher apparent density after treatment. For the examples above, the apparent density was 1.60 g/cm³ before treatment and 2.8 g/cm³ after treatment. The apparent density of the final crystal was 3.18 g/cm³. Densification allows more material to be loaded into the growth chamber to obtain a larger crystal. At temperatures below melting, the densification is achieved by sintering the fluoride raw material. At temperatures above melting point, the densification is achieved by melting and solidifying the fluoride raw material into a solid premelt body. The solidification step does not include crystal growth in the sense of moving the melt through a thermal gradient. Before growing the crystal, the sintered powder or solid premelt body will typically need to be crushed to facilitate melting

Those skilled in the art will appreciate that a variety of reaction chamber and reaction vessel designs may be used to carry out the process described above. The control valve and heater designs may be suitably adjusted to achieve desired flow gas rates and reaction chamber temperature distribution, respectively. The flow rate and heating schedule are flexible. When treating large amounts of powder, various means may be used to agitate the reaction chamber to ensure that fresh surface area of raw material is exposed to the gaseous fluoride during the treatment process.

While the invention has been described with respect to a limited number of embodiments, those skilled in the art, having benefit of this disclosure, will appreciate that other embodiments can be devised which do not depart from the scope of the invention as disclosed herein.

What is claimed is:

1. A method for making a below 200-nm wavelength optical fluoride crystal feedstock, comprising:
loading a fluoride raw material into a chamber;
exposing the fluoride raw material to a flow of gaseous fluoride at a predetermined temperature; and
storing the exposed fluoride raw material in a dry atmosphere.

2. The method of claim 1, wherein the gaseous fluoride comprises one selected from the group consisting of CF₄, NF₃, BF₃, SF₆, C₂F₄, F₂, and mixtures thereof.

3. The method of claim 1, wherein the gaseous fluoride comprises XeF₂.

4. The method of claim 3, further comprising converting the XeF₂ into the gas phase prior to exposing the fluoride raw material.

5. The method of claim 1, wherein the flow of gaseous fluoride comprises an inert gas.

6. The method of claim 1, wherein loading the fluoride raw material into the chamber comprises purging the chamber with an inert gas.

7. The method of claim 1, wherein loading the fluoride raw material into the chamber comprises reducing the pressure in the chamber to vacuum pressure.

8. The method of claim 1, wherein the fluoride raw material comprises one selected from the group consisting of CaF₂, BaF₂, SrF₂, LiF, MgF₂, NaF, and M₃AlF₆, where M represents an element selected from the group consisting of Li, Na, K, Rb, and Cs.

9. The method of claim 1, further comprising drying the fluoride raw material under an inert atmosphere prior to exposing the fluoride raw material to the flow of gaseous fluoride.

10. The method of claim 1, wherein exposing the fluoride raw material comprises densifying the fluoride raw material.

11. The method of claim 10, wherein densifying the fluoride raw material comprises sintering the fluoride raw material.

12. The method of claim 10, wherein densifying the fluoride raw material comprises melting and solidifying the fluoride raw material into a solid premelt body.

13. The method of claim 1, wherein the predetermined temperature is in a range from 50° C. below to 100° C. above a melting point of the fluoride raw material.

14. A method for making a below 200-nm wavelength optical fluoride crystal feedstock, comprising:
loading a fluoride raw material in powder form into a chamber;
exposing the fluoride raw material to a flow of gaseous fluoride at a predetermined temperature;
agitating the chamber so as to expose surfaces of the fluoride raw material to the flow of gaseous fluoride; and storing the exposed fluoride raw material in a dry atmosphere.

15. The method of claim 14, wherein agitating the chamber comprises selectively rotating the chamber.

16. The method of claim 15, wherein selectively rotating the chamber comprises rotating the chamber at a speed ranging from 0 to 200 rpm.

17. The method of claim 14, wherein the gaseous fluoride comprises at least one selected from the group consisting of CF₄, NF₃, BF₃, SF₆, C₂F₄, F₂, CF₃Cl, CF₂Cl₂, CFCl₃ and mixtures thereof.

18. The method of claim 14, wherein the gaseous fluoride comprises XeF₂.

19. The method of claim 18, further comprising converting the XeF₂ into the gas phase prior to exposing the fluoride material.

20. The method of claim 14, wherein the flow of gaseous fluoride comprises an inert gas.

21. The method of claim 14, wherein loading the fluoride raw material into the chamber comprises purging the chamber with an inert gas.

22. The method of claim 14, wherein loading the fluoride raw material into the chamber comprises reducing the pressure in the chamber to vacuum pressure.

23. The method of claim 14, wherein the fluoride raw material comprises one selected from the group consisting of CaF₂, BaF₂, SrF₂, LiF, MgF₂, NaF, and M₃AlF₆, where M represents an element selected from the group consisting of Li, Na, K, Rb, and Cs.

24. The method of claim 14, further comprising heating the fluoride raw material under a drying inert atmosphere prior to exposing the fluoride raw material to the flow of gaseous fluoride.

25. The method of claim 14, wherein exposing the fluoride raw material comprises densifying the fluoride raw material.

26. A method for manufacturing an optical crystal for transmitting light of a wavelength less than 200 nm, comprising:
loading a fluoride raw material treated by exposure to a flow of gaseous fluoride into a crucible;
adding a solid fluorinating agent to the fluoride raw material;
melting the fluoride raw material and solid fluorinating agent; and
growing the crystal by moving the melted fluoride raw material through a thermal gradient.

27. The method of claim 26, wherein the fluoride raw material is loaded into the crucible in a dry atmosphere.

28. The method of claim 26, wherein growing the crystal comprises growing the crystal from a 111 crystal seed.

29. The method of claim 26, wherein growing the crystal comprises growing the crystal from a 001 crystal seed.

30. The method of claim 26, wherein the amount of the solid fluorinating agent added to the fluoride raw material is at most 1% by weight.

31. The method of claim 26, wherein the amount of the solid fluorinating agent added to the fluoride raw material is at most 0.5% by weight.

32. The method of claim 26, wherein the amount of the solid fluorinating agent added to the fluoride raw material is at most 0.1% by weight.

33. The method of claim 26, wherein the solid fluorinating agent comprises at least one solid fluorinating agent chosen from the solid fluorinating agent group consisting of PbF₂, XeF₂ , and ZnF₂.

34. A method for manufacturing an optical fluoride crystal for transmitting light of a wavelength less than 200 nm, comprising:
loading a fluoride raw material into a controlled atmosphere chamber;
heating the fluoride raw material to a predetermined temperature;
exposing the fluoride raw material to a drying inert gas at least through a portion of the heating the fluoride raw material to the predetermined temperature;
exposing the fluoride raw material to a flow of gaseous fluoride at the predetermined temperature to provide a fluoride raw material having a maximum oxygen content of 100 ppm;
melting the fluoride raw material having a maximum oxygen content of 100 ppm; and
crystallizing the melted fluoride raw material to form a crystal having an internal transmission of at least 95%/cm at 157 nm.

35. The method of claim 34, wherein exposing the fluoride raw material comprises densifying the fluoride raw material.

36. The method of claim 34, wherein the fluoride raw material has an oxygen content below 50 ppm.

37. The method of claim 34, further comprising adding a solid fluorinating agent to the fluoride raw material prior to melting the fluoride raw material.

38. The method of claim 34, further comprising loading the fluoride raw material exposed to the flow of gaseous fluoride into a crucible prior to melting the fluoride raw material.

39. An optical fluoride crystal blank for transmitting light of a wavelength less than 200 nm, the optical fluoride crystal having a maximum oxygen content of 50 ppm and an internal transmission of at least 95%/cm at 157 nm.

40. An apparatus for removing oxide impurities from a fluoride salt, comprising:
a chamber into which the fluoride salt is loaded, the chamber having an inlet end and an outlet end;
a pair of porous membranes mounted at the inlet and outlet ends.
means for rotating the chamber; and
means for heating the chamber.

41. The apparatus of claim 40, wherein the chamber and the porous membranes are made of an inert material.

42. The apparatus of claim 41, wherein the inert material is selected from the group consisting of graphite, boron nitride, silicon nitride, silicon carbide, alumina, and quartz.

43. The apparatus of claim 40, wherein the chamber is encased within a vessel made of a corrosion-resistant material.

44. A method for manufacturing an optical fluoride crystal for transmitting light of a wavelength less than 200 nm, comprising:
providing a fluoride raw material having an oxygen content >100 ppm by weight,
loading the fluoride raw material into a controlled atmosphere chamber;
heating the fluoride raw material to a predetermined temperature;
exposing the fluoride raw material to a drying inert gas at least through a portion of the heating the fluoride raw material to the predetermined temperature;
exposing the fluoride raw material to a flow of gaseous fluoride at the predetermined temperature to provide a fluoride raw material having a maximum oxygen content of 50 ppm by weight;
loading the fluoride raw material exposed to the flow of gaseous fluoride into a crucible,
adding a solid fluorinating agent to the fluoride raw material prior to melting the fluoride raw material and melting the fluoride raw material having a maximum oxygen content of 50 ppm by weight; and
crystallizing the melted fluoride raw material to form a fluoride crystal having a maximum oxygen content of 50 ppm by weight and an internal transmission of at least 95%/cm at 157 nm.

45. The method of claim 44, wherein said flow of gaseous fluoride includes CF₄ and the fluoride raw material having an oxygen content >100 ppm by weight is comprised of CaF₂ and said predetermined temperature is at least 1000 degrees C.

46. The method of claim 45, wherein adding a solid fluorinating agent to the fluoride raw material prior to melting the fluoride raw material includes adding at most 1% by weight of said solid fluorinating agent to the fluoride raw material.

47. The method of claim 46 wherein adding a solid fluorinating agent to the fluoride raw material includes adding lead fluoride.

48. The method of claim 46 wherein adding a solid fluorinating agent to the fluoride raw material includes adding zinc fluoride.

49. The method of claim 46, said method including storing the exposed fluoride raw material in a sealed dry atmosphere between said exposing and said loading into said crucible.

50. The method of claim 49, said method including storing the exposed fluoride raw material for a maximum duration of 60 days.

51. The method of claim 46, said providing a fluoride raw material comprising providing a mixture of CaF₂+BaF₂+SrF₂

52. The method of claim 46, said providing a fluoride raw material comprising providing a mixture of CaF₂+BaF₂.

53. The method of claim 46, said providing a fluoride raw material comprising providing a mixture of CaF₂+SrF₂.

54. A method for manufacturing an optical fluoride crystal for transmitting light of a wavelength less than 200 nm, comprising:
providing a fluoride raw material comprised of barium fluoride, the fluoride raw material having an oxygen content >100 ppm by weight,
loading the fluoride raw material into a controlled atmosphere chamber;
heating the fluoride raw material to a predetermined temperature;
exposing the fluoride raw material to a drying inert gas at least through a portion of the heating the fluoride raw material to the predetermined temperature;
exposing the fluoride raw material to a flow of gaseous fluoride at the predetermined temperature to provide a fluoride raw material having a maximum oxygen content of 50 ppm by weight, the flow of gaseous fluoride including F₂;
loading the fluoride raw material exposed to the flow of gaseous fluoride into a crucible,
adding a solid fluorinating agent to the fluoride raw material prior to melting the fluoride raw material and melting the fluoride raw material having a maximum oxygen content of 50 ppm by weight; and
crystallizing the melted fluoride raw material to form a fluoride crystal comprised of barium fluoride having a maximum oxygen content of 50 ppm by weight and an internal transmission of at least 95%/cm at 157 nm.

55. The method of claim 54, wherein adding a solid fluorinating agent to the fluoride raw material prior to melting the fluoride raw material includes adding at most 1% by weight of said solid fluorinating agent to the fluoride raw material.

56. The method of claim 55 wherein adding a solid fluorinating agent to the fluoride raw material includes adding lead fluoride.

57. The method of claim 55 wherein adding a solid fluorinating agent to the fluoride raw material includes adding zinc fluoride.

58. The method of claim 54, said method including storing the exposed fluoride raw material in a sealed dry atmosphere between said exposing and said loading into said crucible.

59. The method of claim 58, said method including storing the exposed fluoride raw material for a maximum duration of 60 days.
